(19) United States
(12) Patent Application Publication
(10) Pub. No.: US 2025/0201523 A1
(43) Pub. Date: Jun. 19, 2025

(54) SHOWERHEAD UNIT AND SUBSTRATE TREATING APPARATUS INCLUDING THE SAME

(71) Applicant: SEMES CO., LTD., Cheonan-si (KR)

(72) Inventors: Ji Hoon LEE, Chungcheongnam-do (KR); Ha Yeong CHOI, Chungcheongnam-do (KR)

(73) Assignee: SEMES CO., LTD., Cheonan-si (KR)

(21) Appl. No.: 18/938,859

(22) Filed: Nov. 6, 2024

(30) Foreign Application Priority Data
Dec. 18, 2023 (KR) 10-2023-0184248

(51) Int. Cl. H01J 37/32; H01L 21/67

(52) U.S. Cl. CPC H01J 37/32449; H01L 21/67167

(57) ABSTRACT

A showerhead unit that controls plasma confinement by using an upper ground ring and a substrate treating apparatus including the same are provided. The substrate treating apparatus comprises a chamber housing providing a space in which a substrate is treated; a substrate support unit disposed inside the chamber housing, supporting the substrate; a showerhead unit disposed inside the chamber housing, providing a process gas; and a plasma generating unit generating plasma for treating the substrate by using the process gas, wherein the showerhead unit includes: a showerhead main body that includes a plurality of gas feeding holes to provide the process gas; and an upper ring assembly surrounding the showerhead main body, and the upper ring assembly includes a portion extended in a direction in which the substrate support unit is positioned.

### CROSS-REFERENCE TO RELATED APPLICATION

This application claims priority from Korean Patent Application No. 10-2023-0184248 filed on Dec. 18, 2023 in the Korean Intellectual Property Office and all the benefits accruing therefrom under 35 U.S.C. 119, the contents of which in its entirety are herein incorporated by reference.

### BACKGROUND

### Technical Field

The present disclosure relates to a showerhead unit applied to a facility for treating a substrate by using plasma, and a substrate treating apparatus including the same.

### Description of the Related Art

In case of a substrate treating apparatus that treats a substrate by using plasma, a plasma zone may be formed between a showerhead that provides a process gas and an electro-static chuck that supports the substrate.

Recently, in order to improve a High Aspect Ratio Contact (HARC) process, plasma confinement has been attempted by changing a hardware structure of the substrate treating apparatus. However, since both the showerhead and the electro-static chuck have a flat structure for the plasma zone, it is difficult to perform plasma confinement.

### BRIEF SUMMARY

An object of the present disclosure is to provide a showerhead unit that controls plasma confinement by using an upper ground ring and a substrate treating apparatus including the same.

The objects of the present disclosure are not limited to those mentioned above and additional objects of the present disclosure, which are not mentioned herein, will be clearly understood by those skilled in the art from the following description of the present disclosure.

A substrate treating apparatus according to one aspect of the present disclosure devised to achieve the above objects comprises a chamber housing providing a space in which a substrate is treated; a substrate support unit disposed inside the chamber housing, supporting the substrate; a showerhead unit disposed inside the chamber housing, providing a process gas; and a plasma generating unit generating plasma for treating the substrate by using the process gas, wherein the showerhead unit includes: a showerhead main body that includes a plurality of gas feeding holes to provide the process gas; and an upper ring assembly surrounding the showerhead main body, and the upper ring assembly includes a portion extended in a direction in which the substrate support unit is positioned.

A showerhead unit according to one aspect of the present disclosure devised to achieve the above objects is installed in an apparatus for treating a substrate by using plasma, and comprises an inner showerhead including a plurality of gas feeding holes providing a process gas for generating the plasma; an outer showerhead surrounding the inner showerhead; and an upper ring assembly surrounding the outer showerhead, wherein the upper ring assembly includes a portion extended in a direction in which the substrate support unit is positioned.

A substrate treating apparatus according to another aspect of the present disclosure devised to achieve the above objects comprises a chamber housing providing a space in which a substrate is treated; a substrate support unit disposed inside the chamber housing, supporting the substrate; a showerhead unit disposed inside the chamber housing, providing a process gas; and a plasma generating unit generating plasma for treating the substrate by using the process gas, wherein the showerhead unit includes: an inner showerhead including a plurality of gas feeding holes for providing the process gas; an outer showerhead surrounding the inner showerhead; and an upper ring assembly surrounding the outer showerhead, the upper ring assembly includes: a first portion; a second portion disposed on one side below the first portion; and a third portion disposed on the other side below the first portion, grounded and disposed to be closer to the outer showerhead than the second portion, and the third portion includes: a spacer providing a constant spacing between the outer showerhead and the second portion; and a bulk liner coupled to the spacer and extended in a direction in which the substrate support unit is positioned.

Details of the other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary plan view illustrating an internal structure of a semiconductor manufacturing facility according to the first embodiment;

FIG. 2 is an exemplary plan view illustrating an internal structure of a semiconductor manufacturing facility according to the second embodiment;

FIG. 3 is an exemplary plan view illustrating an internal structure of a semiconductor manufacturing facility according to the third embodiment;

FIG. 4 is an exemplary cross-sectional view illustrating an internal structure of a substrate treating apparatus according to the first embodiment;

FIG. 5 is an exemplary cross-sectional view illustrating an internal structure of a substrate treating apparatus according to the second embodiment;

FIG. 6 is an exemplary cross-sectional view illustrating an internal structure of a substrate treating apparatus according to the third embodiment;

FIG. 7 is an exemplary view illustrating an internal structure of a showerhead unit according to the first embodiment of the present disclosure;

FIG. 8 is an exemplary view illustrating an internal structure of an upper ring assembly according to the first embodiment of the present disclosure;

FIG. 9 is an exemplary view illustrating structural characteristics of a bulk liner according to the first embodiment of the present disclosure;

FIG. 10 is an exemplary view illustrating structural characteristics of a bulk liner according to the second embodiment of the present disclosure;

FIG. 11 is an exemplary view illustrating structural characteristics of a bulk liner according to the third embodiment of the present disclosure;

FIG. 12 is an exemplary view illustrating structural characteristics of a bulk liner according to the fourth embodiment of the present disclosure;

FIG. 13 is an exemplary view illustrating structural characteristics of a bulk liner according to the fifth embodiment of the present disclosure;

FIG. 14 is an exemplary view illustrating structural characteristics of a bulk liner according to the sixth embodiment of the present disclosure;

FIG. 15 is an exemplary view illustrating structural characteristics of a bulk liner according to the seventh embodiment of the present disclosure;

FIG. 16 is a first exemplary view illustrating structural characteristics of a bulk liner according to the eighth embodiment of the present disclosure;

FIG. 17 is a second exemplary view illustrating structural characteristics of a bulk liner according to the eighth embodiment of the present disclosure;

FIG. 18 is a third exemplary view illustrating structural characteristics of a bulk liner according to the eighth embodiment of the present disclosure;

FIG. 19 is an exemplary view illustrating an internal structure of an upper ring assembly according to the second embodiment of the present disclosure; and

FIG. 20 is an exemplary view illustrating an internal structure of a showerhead unit according to the second embodiment of the present disclosure.

### DETAILED DESCRIPTION OF THE DISCLOSURE

Hereinafter, the embodiment of the present disclosure will be described in detail with reference to the accompanying drawings. The same reference numerals will be used for the same elements on the drawings, and their redundant description will be omitted.

The present disclosure relates to a substrate treating apparatus for treating a substrate by using plasma and a semiconductor manufacturing facility including a plurality of substrate treating apparatuses. The substrate treating apparatus may include a showerhead unit that provides a process gas to generate plasma. The showerhead unit may control plasma confinement by using an upper ground ring (UGR).

Hereinafter, the substrate treating apparatus and the semiconductor manufacturing facility will be first described, and then a showerhead unit including an upper ground ring will be described.

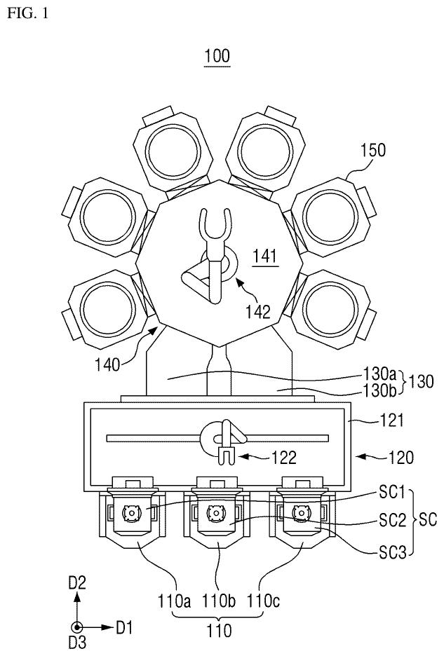

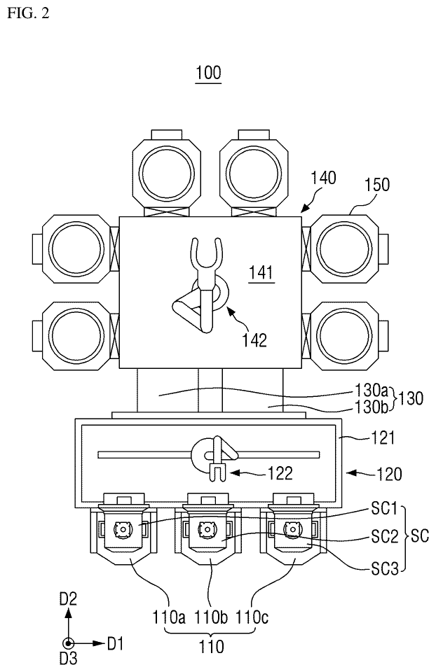

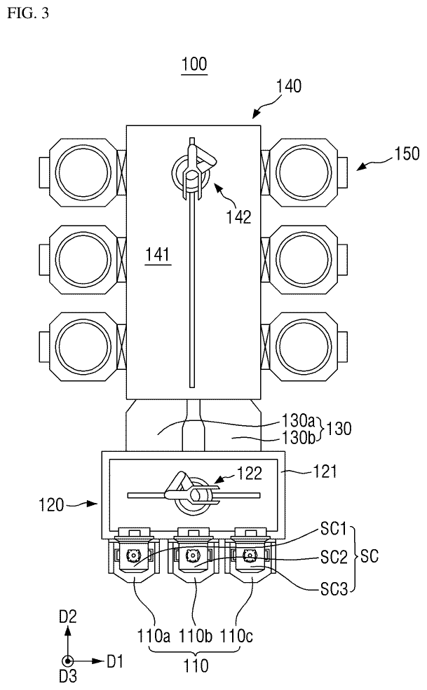

FIG. 1 is an exemplary plan view illustrating an internal structure of a semiconductor manufacturing facility according to the first embodiment. FIG. 2 is an exemplary plan view illustrating an internal structure of a semiconductor manufacturing facility according to the second embodiment. FIG. 3 is an exemplary plan view illustrating an internal structure of a semiconductor manufacturing facility according to the third embodiment.

A first direction D1 and a second direction D2 constitute a plane in a horizontal direction. For example, the first direction D1 may be a front-rear direction, and the second direction D2 may be a left-right direction. Alternatively, the first direction D1 may be a left-right direction, and the second direction D2 may be a front-rear direction. A third direction D3 is a height direction, and is a direction perpendicular to a plane constituted by the first direction D1 and the second direction D2. The third direction D3 may be a vertical direction.

According to FIGS. 1 to 3, a semiconductor manufacturing facility 100 may include a load port module 110, an index module 120, a load lock chamber 130, a transfer module 140, and a process chamber 150.

The semiconductor manufacturing facility 100 is a system that treats a substrate by using an etching process, a cleaning process, a deposition process, or the like. The semiconductor manufacturing facility 100 may include one process chamber, but may include a plurality of process chambers without being limited thereto. The plurality of process chambers may include the same kind of process chambers, but may include different kinds of process chambers without being limited thereto. When the semiconductor manufacturing facility 100 includes a plurality of process chambers, it may be provided as a multi-chamber substrate treating system.

The load port module 110 is provided to allow a container SC, on which a plurality of substrates are mounted, to be seated thereon. For example, the container SC may be a Front Opening Unified Pod (FOUP).

In the load port module 110, the container SC may be loaded or unloaded. Also, in the load port module 110, the substrate accommodated in the container SC may be loaded or unloaded.

When a loading or unloading target is the container SC, a container carrying device may load or unload the container SC on or from the load port module 110. In detail, the container SC gripped by the container carrying device may be seated on the load port module 110, thereby loading the container SC on the load port module 110. In addition, the container carrying device may unload the container SC from the load port module 110 by gripping the container SC seated on the load port module 110. Although not shown in FIGS. 1 to 3, the container carrying device may be an Overhead Hoist Transporter (OHT).

When the loading or unloading target is the substrate, a first transfer robot 122 may load or unload the substrate in or from the container SC seated on the load port module 110. In case of unloading of the substrate, when the container SC is seated on the load port module 110, the first transfer robot 122 may access the load port module 110 and then may take out the substrate from the container SC. In case of loading of the substrate, when the substrate is completely treated in the process chamber 150, the first transfer robot 122 may take out the substrate from the load lock chamber 130 and then carry the substrate into the container SC.

The load port module 110 may be disposed in front of the index module 120 as a plural number. For example, three load port modules 110a, 110b and 110c such as a first load port module 110a, a second load port module 110b and a third load port module 110c may be disposed in front of the index module 120.

When the plurality of load port modules 110 are disposed in front of the index module 120, the container SC seated on each load port module may be loaded with different types of objects. For example, when the first load port module 110a, the second load port module 110b and the third load port module 110c are disposed in front of the index module 120, a first container SC1 seated on the first load port module 110a may be loaded with a wafer-type sensor, a second container SC2 seated on the second load port module 110b may be loaded with the substrate, that is, a wafer, and a third container SC3 seated on the third load port module 110c may be loaded with consumable components such as a focus ring and an edge ring.

However, the present embodiment is not limited to the above example. The container SC seated on each load port module may be loaded with the same types of objects. Alternatively, among the plurality of load port modules, the containers seated on some load port modules may be loaded with the same type of objects, and the containers seated on some other load port modules may be loaded with different types of objects.

The index module 120 is disposed between the load port module 110 and the load lock chamber 130, and may be provided as an interface so that the substrate may be transferred between the container SC on the load port module 110 and the load lock chamber 130.

The index module 120 may include a first module housing 121 and a first transfer robot 122. The first transfer robot 122 is disposed inside the first module housing 121, and may transfer the substrate between the load port module 110 and the load lock chamber 130. An internal environment of the first module housing 121 is provided as an atmospheric pressure environment, and the first transfer robot 122 may be operated in the atmospheric pressure environment. One first transfer robot 122 may be provided in the first module housing 121, but the present disclosure is not limited thereto, and a plurality of first transfer robots 122 may be also provided.

Although not shown in FIGS. 1 to 3, the index module 120 may include a buffer chamber. The buffer chamber may temporarily store an untreated substrate before being transferred to the load lock chamber 130. Further, the buffer chamber may temporarily store a pre-treated substrate before being transferred to the container SC on the load port module 110. The buffer chamber may be provided on the other sidewalls except a sidewall adjacent to the load port module 110 or a sidewall adjacent to the load lock chamber 130, but the present disclosure is not limited thereto, and may be also provided on the sidewall adjacent to the load port module 110. Alternatively, the buffer chamber may be provided on the sidewall adjacent to the load lock chamber 130.

In the present embodiment, a front end module (FEM) may be provided on one side of the load lock chamber 130. The front end module (FEM) may include a load port module 110 and an index module 120, and for example, may be provided as an Equipment Front End Module (EFEM).

As described above, the load port module 110 may be provided in the semiconductor manufacturing facility 100 as a plural number. Referring to the examples of FIGS. 1 to 3, the plurality of load port modules may have a structure in which they are arranged in a horizontal direction D1, but the present disclosure is not limited thereto. The plurality of load port modules may also have a structure in which they are stacked in a vertical direction D3. When the plurality of load port modules are stacked in the vertical direction, the front end module may be provided as a vertically stacked EFEM.

The load lock chamber 130 may serve as a buffer chamber between an input port and an output port in the semiconductor manufacturing facility 100. That is, the load lock chamber 130 may serve to temporarily store the untreated substrate or the pre-treated substrate between the load port module 110 and the process chamber 150. Although not shown in FIGS. 1 to 3, the load lock chamber 130 may include a buffer stage for temporarily storing the substrate therein.

The load lock chamber 130 may be disposed between the index module 120 and the transfer module 140 as a plural number. For example, two load lock chambers 130a and 130b, such as a first load lock chamber 130a and a second load lock chamber 130b, may be disposed between the index module 120 and the transfer module 140.

The plurality of load lock chambers may be disposed in the same direction as an arrangement direction of the plurality of load port modules. Referring to the examples of FIGS. 1 to 3, the first load lock chamber 130a and the second load lock chamber 130b may be disposed in the same direction as the arrangement direction of the three load port modules 110a, 110b, and 110c between the index module 120 and the transfer module 140, i.e., in the horizontal direction D1. The first load lock chamber 130a and the second load lock chamber 130b may be provided in a mutually symmetrical single layered structure in which they are disposed to be spaced apart from each other in the horizontal direction.

However, the present embodiment is not limited to the above example. The plurality of load lock chambers may be disposed in a direction different from the arrangement direction of the plurality of load port modules. The first load lock chamber 130a and the second load lock chamber 130b may be disposed in a direction different from the arrangement direction of the three load port modules 110a, 110b and 110c between the index module 120 and the transfer module 140, i.e., in the vertical direction D3. The first load lock chamber 130a and the second load lock chamber 130b may be provided in a double-layered structure in which they are disposed to be spaced apart from each other in the vertical direction.

Any one of the first load lock chamber 130a and the second load lock chamber 130b may temporarily store the untreated substrate transferred from the index module 120 to the transfer module 140. Furthermore, the other load lock chamber may temporarily store the pre-treated substrate transferred from the transfer module 140 to the index module 120. However, the present disclosure is not limited to the above example. The first load lock chamber 130a and the second load lock chamber 130b may commonly serve as both a temporary storage of the untreated substrate and a temporary storage of the pre-treated substrate.

The load lock chamber 130 may change its inside to any one of a vacuum environment and an atmospheric pressure environment by using a gate valve or the like. In detail, when the first transfer robot 122 of the index module 120 loads the substrate into the load lock chamber 130 or the first transfer robot 122 unloads the substrate from the load lock chamber 130, the load lock chamber 130 may form its inside in an environment the same as or similar to an internal environment of the index module 120. Furthermore, when the second transfer robot 142 of the transfer module 140 loads the substrate into the load lock chamber 130 or the second transfer robot 142 unloads the substrate from the load lock chamber 130, the load lock chamber 130 may form its inside in an environment the same as or similar to an internal environment of the transfer module 140. Therefore, the load lock chamber 130 may prevent an inner air pressure state of the index module 120 or an inner air pressure state of the transfer module 140 from being changed.

The transfer module 140 is disposed between the load lock chamber 130 and the process chamber 150, and may be provided as an interface so that the substrate may be transferred between the load lock chamber 130 and the process chamber 150.

The transfer module 140 may include a second module housing 141 and a second transfer robot 142. The second transfer robot 142 is disposed inside the second module housing 141, and may transfer the substrate between the load lock chamber 130 and the process chamber 150. An internal environment of the second module housing 141 is provided as a vacuum environment, and the second transfer robot 142 may operate in the vacuum environment. One second transfer robot 142 may be provided inside the second module housing 141, but may be provided as a plural number without being limited thereto.

The transfer module 140 may be connected to the plurality of process chambers 150. To this end, the second module housing 141 may include a plurality of sides, and the second transfer robot 142 may be freely rotated through each side of the second module housing 141 so that the substrate may be loaded in the plurality of process chambers 150 or may be unloaded from the plurality of process chambers 150.

The process chamber 150 serves to treat the substrate. When the untreated substrate is provided, the process chamber 150 may treat the substrate and provide the pre-treated substrate to the load lock chamber 130 through the transfer module 140. A more detailed description of the process chamber 150 will be given later.

When the semiconductor manufacturing facility 100 includes the plurality of process chambers, the semiconductor manufacturing facility 100 may be formed in a structure having a cluster platform. For example, the plurality of process chambers may be disposed in a cluster manner based on the transfer module 140 as illustrated in FIG. 1, but the present embodiment is not limited thereto. When the semiconductor manufacturing facility 100 includes the plurality of process chambers, the semiconductor manufacturing facility 100 may be formed in a structure having a quad platform. For example, the plurality of process chambers may be disposed in a quad manner based on the transfer module 140 as illustrated in the example of FIG. 2. Alternatively, when the semiconductor manufacturing facility 100 includes the plurality of process chambers, the semiconductor manufacturing facility 100 may be formed in a structure having an in-line platform. For example, the plurality of process chambers may be disposed in an in-line manner based on the transfer module 140 as illustrated in the example of FIG. 3, and two different process chambers may be disposed in series while forming a corresponding relationship on both sides of the transfer module 140.

Although not shown in FIGS. 1 to 3, the semiconductor manufacturing facility 100 may further include a control device. The control device serves to control the entire operation of each module constituting the semiconductor manufacturing facility 100. For example, the control device may control the substrate transfer of the first transfer robot 122 or the second transfer robot 142, control a change in an internal environment of the load lock chamber 130 and control an overall substrate treating process of the process chamber 150.

The control device may include a processor for controlling each component constituting the semiconductor manufacturing facility 100, a network for wired or wireless communication with each component, one or more instructions related to a function or operation for controlling each component, a storage means for storing processing recipes including the instructions, various data, and the like. In addition, the control device may further include a user interface that includes an input means for allowing an operator to perform a command input manipulation or the like to manage the semiconductor manufacturing facility 100 and an output means for visualizing and displaying an actuation status of the semiconductor manufacturing facility 100. The control device may be provided as a computing device for data processing, analysis, and command transmission.

The instruction may be provided in the form of a computer program or an application. The computer program may include one or more instructions and thus may be stored in a computer-readable recording medium. The instruction may include a code generated by a compiler, a code capable of being executed by an interpreter, and the like. The storage means may be provided as one or more storage media selected from a flash memory, an HDD, an SSD, a card type memory, a RAM, an SRAM, a ROM, an EEPROM, a PROM, a magnetic memory, a magnetic disk and an optical disk.

Next, the process chamber 150 will be described. A surface of the process chamber 150 may be made of alumite formed with an anodized film, and an inside thereof may be configured to be air tight. The process chamber 150 may be provided in the semiconductor manufacturing facility 100 as a plural number, and the plurality of process chambers may be disposed to be spaced apart from each other around the transfer module 140, but the present disclosure is not limited thereto, and the process chamber 150 may be also provided in the semiconductor manufacturing facility 100 as a single number. The process chamber 150 may be provided in a cylindrical shape, but is not limited thereto, and may be provided in a shape other than the cylindrical shape.

As described above, the process chamber 150 may treat the substrate. Hereinafter, the process chamber 150 will be defined as the substrate treating apparatus and the internal structure of the process chamber 150 will be described.

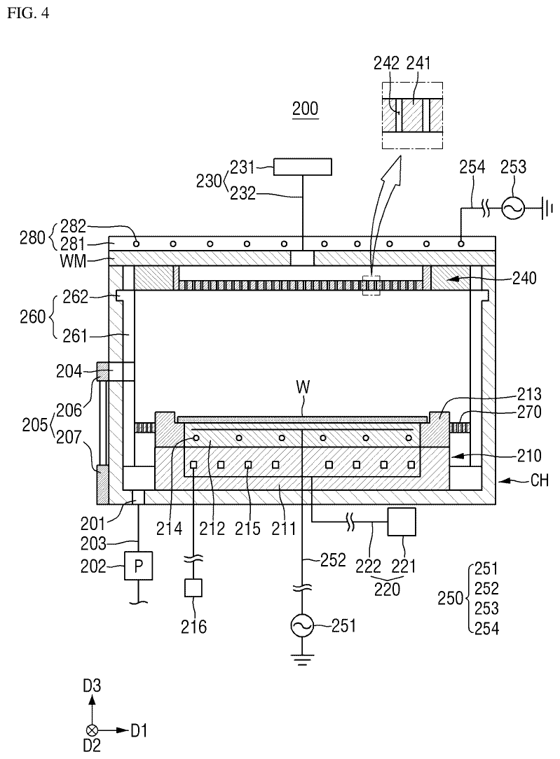

FIG. 4 is an exemplary cross-sectional view illustrating an internal structure of a substrate treating apparatus according to the first embodiment. According to FIG. 4, the substrate treating apparatus 200 may include a chamber housing CH, a substrate support unit 210, a cleaning gas supply unit 220, a process gas supply unit 230, a showerhead unit 240, a plasma generating unit 250, a liner unit 260, a baffle unit 270, a window module WM, and an antenna unit 280.

The substrate treating apparatus 200 may treat the substrate W by using plasma. The substrate treating apparatus 200 may treat the substrate W in a dry method. The substrate treating apparatus 200 may treat the substrate W, for example, in a vacuum environment. The substrate treating apparatus 200 may treat the substrate W by using an etching process, but is not limited thereto, and the substrate treating apparatus 200 may also treat the substrate W by using a deposition process or a cleaning process.

The chamber housing CH provides a space in which a process of treating the substrate W by using plasma, that is, a plasma process is executed. A surface of the chamber housing CH may be made of alumite formed with an anodized film, and an inside thereof may be configured to be air tight. The chamber housing CH may be provided in a cylindrical shape, but is not limited thereto, and may be provided in a shape other than the cylindrical shape. The chamber housing CH may have an exhaust hole 201 in a lower portion thereof.

The exhaust hole 201 may be connected to an exhaust line 203 on which a pump 202 is mounted. The exhaust hole 201 may discharge reaction by-products generated during the plasma process and a gas remaining inside the chamber housing CH to the outside of the chamber housing CH through the exhaust line 203. In this case, an inner space of the chamber housing CH may be decompressed.

An opening 204 may be formed to pass through a sidewall of the chamber housing CH. The opening 204 may be provided as a passage through which the substrate W enters and exits the chamber housing CH. The opening 204 may be configured to be automatically opened and closed by, for example, a door assembly 205.

The door assembly 205 may include an outer door 206 and a door driver 207. The outer door 206 may open and close the opening 204 on an outer wall of the chamber housing CH. The outer door 206 may be moved in the height direction D3 of the substrate treating apparatus 200 under the control of the door driver 207. The door driver 207 may operate using at least one element selected from a motor, a hydraulic cylinder and a pneumatic cylinder.

The substrate support unit 210 is installed in an inner lower zone of the chamber housing CH. The substrate support unit 210 may adsorb and support the substrate W by using an electro-static force. For example, the substrate support unit 210 may be provided as an electro-static chuck (ESC), but is not limited thereto. The substrate support unit 210 may support the substrate W by using various other methods such as vacuum and mechanical clamping.

When the substrate support unit 210 is provided as an electro-static chuck (ESC), the substrate support unit 210 may include a base plate 211 and a dielectric layer 212. The dielectric layer 212 is disposed on the base plate 211 and may adsorb and support the substrate W seated thereon. The base plate 211 may be formed of a material having excellent corrosion resistance and heat resistance. The base plate 211 may be provided as, for example, an aluminum body. The dielectric layer 212 may be formed of, for example, a ceramic material.

Although not shown in FIG. 4, the substrate support unit 210 may further include a bonding layer. The bonding layer may bond the base plate 211 to the dielectric layer 212. The bonding layer may include, for example, a polymer.

The ring structure 213 is provided to surround an outer edge zone of the dielectric layer 212. The ring structure 213 may serve to concentrate ions on the substrate W when the plasma process is performed inside the chamber housing CH. The ring structure 213 may be formed of a silicon material. For example, the ring structure 213 may be provided as a focus ring.

Although not shown in FIG. 4, the substrate treating apparatus 200 may further include an edge ring. The edge ring may be provided below or outside the focus ring. The edge ring may serve to prevent a side of the dielectric layer 212 from being damaged by plasma. The edge ring may be formed of an insulator material, for example, ceramic or quartz.

A heating member 214 and a cooling member 215 are provided to maintain the substrate W at a process temperature when the substrate treating process is performed inside the chamber housing CH. The heating member 214 may be installed inside the dielectric layer 212, and may be provided as a heating wire. The cooling member 215 may be installed inside the base plate 211, and may be provided as a cooling pipe through which a refrigerant moves. A cooling device (chiller) 216 may supply the refrigerant to the cooling member 215. The cooling device 216 may use cooling water as the refrigerant, but is not limited thereto, and may further use helium (He) gas. Alternatively, the cooling device 216 may use both cooling water and helium gas as the refrigerant. Meanwhile, the heating member 214 may not be provided inside the substrate support unit 210.

The cleaning gas supply unit 220 provides a cleaning gas to the dielectric layer 212 or the ring structure 213 to remove particles remaining in the dielectric layer 212 or the ring structure 213. For example, the cleaning gas supply unit 220 may provide nitrogen (N₂) gas as the cleaning gas.

The cleaning gas supply unit 220 may include a cleaning gas supply source 221 and a cleaning gas supply pipe 222. The cleaning gas supply pipe 222 may be connected to a space between the dielectric layer 212 and the ring structure 213. The cleaning gas supplied by the cleaning gas supply source 221 may move to a space between the dielectric layer 212 and the ring structure 213 through the cleaning gas supply pipe 222 to remove particles remaining in an edge portion of the dielectric layer 212 or an upper portion of the ring structure 213.

The process gas supply unit 230 provides a process gas to the inner space of the chamber housing CH. The process gas supply unit 230 may provide the process gas to the inner space of the chamber housing CH through a hole formed by passing through an upper cover of the chamber housing CH, that is, the window module WM, but is not limited thereto. The process gas supply unit 230 may also provide the process gas to the inner space of the chamber housing CH through a hole formed by passing through the sidewall of the chamber housing CH.

The process gas supply unit 230 may include a process gas supply source 231 and a process gas supply pipe 232. The process gas supply source 231 may provide a gas used for treating the substrate W as the process gas. The process gas supply source 231 may be provided as a single number in the substrate treating apparatus 200, but may be provided as a plural number without being limited thereto. When the process gas supply source 231 is provided in the substrate treating apparatus 200 as a plural number, the plurality of process gas supply sources 231 may provide the same type of process gas, but are not limited thereto, and may provide different types of process gases.

The showerhead unit 240 sprays the process gas provided from the process gas supply source 231 onto the entire zone of the substrate W disposed in the inner space of the chamber housing CH. The showerhead unit 240 may be connected to the process gas supply source 231 through the process gas supply pipe 232.

The showerhead unit 240 is disposed in the inner space of the chamber housing CH, and may include a plurality of gas feeding holes 242. The plurality of gas feeding holes 242 may be formed to pass through a surface of a main body 241 in the vertical direction D3. The plurality of gas feeding holes 242 may be formed to be spaced apart from each other at a constant interval on the main body 241. The showerhead unit 240 may uniformly spray the process gas to the entire zone of the substrate W through the plurality of gas feeding holes 242.

The showerhead unit 240 may be installed inside the chamber housing CH to face the substrate support unit 210 in the vertical direction D3. The showerhead unit 240 may be provided to have a larger diameter than the dielectric layer 212, but is not limited thereto. The showerhead unit 240 may be provided to have the same diameter as that of the dielectric layer 212. The showerhead unit 240 may be formed of a silicon material, but is not limited thereto. The showerhead unit 240 may be also formed of a metal material.

Although not shown in FIG. 4, the showerhead unit 240 may be divided into a plurality of units. For example, the showerhead unit 240 may be divided into three modules such as a first head module, a second head module and a third head module. The first head module may be disposed at a position corresponding to a center zone of the substrate W. The second head module may be disposed to surround an outer edge of the first head module. The second head module may be disposed at a position corresponding to a middle zone of the substrate W. The third head module may be disposed to surround an outer edge of the second head module. The third head module may be disposed at a position corresponding to an edge zone of the substrate W.

The plasma generating unit 250 generates plasma from a gas remaining in a discharge space. In this case, the discharge space is the inner space of the chamber housing CH, and may be a space formed between the showerhead unit 240 and the window module WM. Alternatively, the discharge space may be a space formed between the substrate support unit 210 and the showerhead unit 240. When the discharge space is the space formed between the substrate support unit 210 and the showerhead unit 240, the discharge space may be divided into a plasma zone and a process zone. The plasma zone may be formed to be higher than the process zone.

The plasma generating unit 250 may generate plasma in the discharge space by using an inducitively coupled plasma (ICP) source. For example, the plasma generating unit 250 may generate plasma in the discharge space by using the substrate support unit 210 and the antenna unit 280 as a first electrode (lower electrode) and a second electrode (upper electrode), respectively, but the present embodiment is not limited thereto.

The plasma generating unit 250 may generate plasma in the discharge space by using a capacitively coupled plasma (CCP) source. For example, the plasma generating unit 250 may generate plasma in the discharge space by using the substrate support unit 210 and the showerhead unit 240 as a first electrode (lower electrode) and a second electrode (upper electrode), respectively. The case that the plasma generating unit 250 is provided as the ICP source will be described herein. The case that the plasma generating unit 250 is provided as the CCP source will be described later.

The plasma generating unit 250 may include a first high frequency power source 251, a first transmission line 252, a second high frequency power source 253, and a second transmission line 254.

The first high frequency power source 251 applies RF power to the first electrode. The first high frequency power source 251 may serve as a plasma source for generating plasma in the chamber housing CH but is not limited thereto. The first high frequency power source 251 may serve to control characteristics of plasma in the chamber housing CH together with the second high frequency power source 253.

The first high frequency power source 251 may be provided in the substrate treating apparatus 200 as a plural number. In this case, the plasma generating unit 250 may include a first matching network electrically connected to each of the first high frequency power sources. The first matching network may serve to match the frequency powers of different magnitudes and apply them to the first electrode when the frequency powers of different magnitudes are input from the plurality of first high frequency power sources.

The first transmission line 252 may connect the first electrode to GND. The first high frequency power source 251 may be installed on the first transmission line 252, but is not limited thereto. The first transmission line 252 may connect the first electrode to the first high frequency power source 251. For example, the first transmission line 252 may be provided as an RF rod.

The second high frequency power source 253 applies RF power to the second electrode. The second high frequency power source 253 may serve to control characteristics of plasma in the chamber housing CH. For example, the second high frequency power source 253 may serve to control ion bombardment energy in the chamber housing CH.

The second high frequency power source 253 may be provided in the substrate treating apparatus 200 as a plural number. In this case, the plasma generating unit 250 may include a second matching network electrically connected to each of the second high frequency power sources. The second matching network may serve to match the frequency powers and apply them to the second electrode when frequency powers of different magnitudes are input from the plurality of second high frequency power sources.

The second transmission line 254 connects the second electrode to the GND. The second high frequency power source 253 may be installed on the second transmission line 254.

The liner unit 260 may be defined as a wall liner, and protects the inside of the chamber housing CH from arc discharge occurring during a process of exciting a process gas or impurities generated during the substrate treating process. The liner unit 260 may be formed to cover an inner wall of the chamber housing CH.

The liner unit 260 may include a support ring 262 on an upper portion of a body 261. The support ring 262 may be protruded from the upper portion of the body 261 in an outward direction D1, and may serve to fix the body 261 to the chamber housing CH.

The baffle unit 270 serves to exhaust a process by-product or an unreacted gas of plasma in the chamber housing CH to the outside. The baffle unit 270 may be installed in a space between the substrate support unit 210 and the inner wall (or the liner unit 260) of the chamber housing CH, and may be installed to be adjacent to the exhaust hole 201. The baffle unit 270 may be provided in a ring shape between the substrate support unit 210 and the inner wall of the chamber housing CH.

The baffle unit 270 may include a plurality of slot holes passing through a body in the vertical direction D3 to control a flow of the process gas in the chamber housing CH. The baffle unit 270 may be formed of a material having etch resistance to minimize damage or deformation by radicals or the like in the inner space of the chamber housing CH, in which plasma is generated. For example, the baffle unit 270 may be formed to include quartz.

The window module WM serves as an upper cover of the chamber housing CH, which seals the inner space of the chamber housing CH. The window module WM may be provided separately from the chamber housing CH, but is not limited thereto, and may be also provided integrally with the chamber housing CH. The window module WM may be formed of a dielectric window made of an insulating material. For example, the window module WM may be formed of alumina. When the plasma process is performed in the inner space of the chamber housing CH, the window module WM may include a coating film on a surface to suppress occurrence of particles.

The antenna unit 280 serves to excite the process gas into plasma by generating a magnetic field and an electric field inside the chamber housing CH. The antenna unit 280 may operate using RF power supplied from the second high frequency power source 253. The antenna unit 280 may be provided on the upper portion of the chamber housing CH. For example, the antenna unit 280 may be provided on the window module WM, but is not limited thereto, and the antenna unit 280 may be provided on the sidewall of the chamber housing CH.

The antenna unit 280 may include an antenna 282 inside or on a surface of the body 281. The antenna 282 may be provided to form a closed loop by using a coil. The antenna 282 may be formed in a spiral shape along a width direction D1 of the chamber housing CH or other various shapes.

The antenna unit 280 may be formed to have a planar type, but is not limited thereto, and the antenna unit 280 may be formed to have a cylindrical type. When the antenna unit 280 is formed to have a planar type, it may be provided on the upper portion of the chamber housing CH. When the antenna unit 280 is formed to have a cylindrical type, it may be provided to surround the outer sidewall of the chamber housing CH.

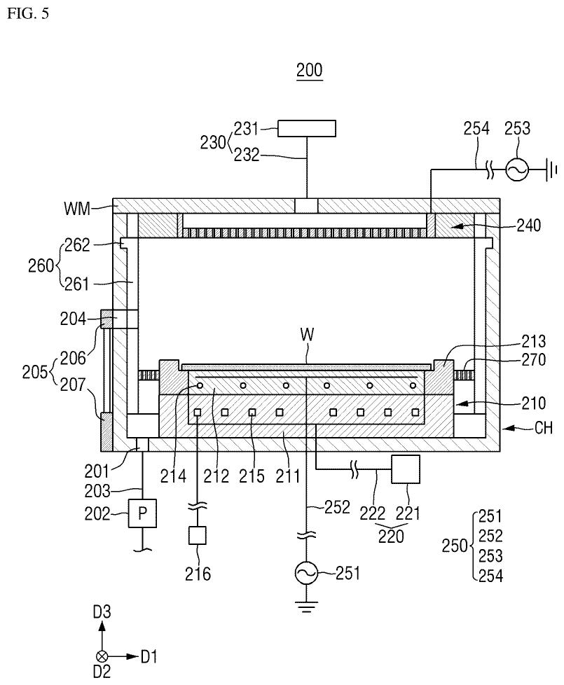

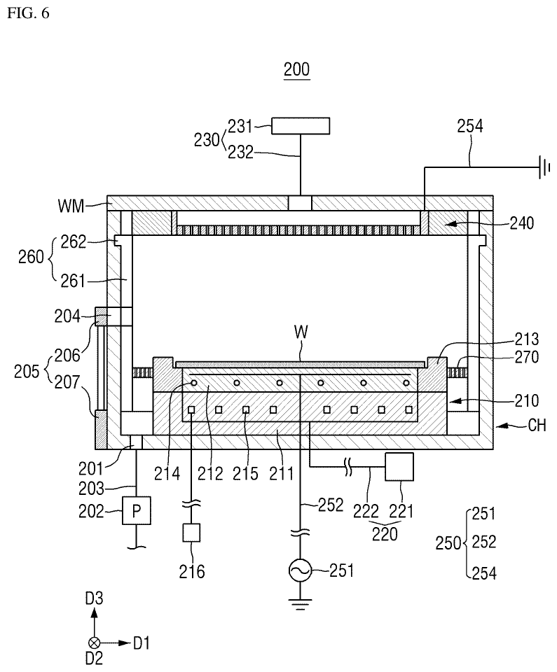

The case that the plasma generating unit 250 is provided as an ICP source has been described with reference to FIG. 4. Hereinafter, the case that the plasma generating unit 250 is provided as a CCP source will be described with reference to FIGS. 5 and 6. Hereinafter, a description of redundant portions as compared with the case of FIG. 4 will be omitted, and only portions corresponding to differences therefrom will be described.

FIG. 5 is an exemplary cross-sectional view illustrating an internal structure of a substrate treating apparatus according to the second embodiment. FIG. 6 is an exemplary cross-sectional view illustrating an internal structure of a substrate treating apparatus according to the third embodiment.

Referring to FIGS. 5 and 6, the substrate treating apparatus 200 may include a chamber housing CH, a substrate support unit 210, a cleaning gas supply unit 220, a process gas supply unit 230, a showerhead unit 240, a plasma generating unit 250, a liner unit 260, a baffle unit 270, and a window module WM. That is, the substrate treating apparatus 200 of FIGS. 5 and 6 may not include an antenna unit 280 as compared with the substrate treating apparatus 200 of FIG. 4.

The plasma generating unit 250 may include a first high frequency power source 251, a first transmission line 252, a second high frequency power source 253, and a second transmission line 254, but is not limited thereto. As shown in FIG. 6, the plasma generating unit 250 may include a first high frequency power source 251, a first transmission line 252, and a second transmission line 254. That is, the plasma generating unit 250 of FIG. 6 may not include a second high frequency power source 253 as compared with the plasma generating unit 250 of FIG. 5.

In case of the example according to FIG. 4, the second transmission line 254 may be connected to the antenna 282 of the antenna unit 280. The second high frequency power source 253 may apply RF power to the antenna 282 of the antenna unit 280. In case of the example according to FIG. 5, the second transmission line 254 may be connected to the main body 241 of the showerhead unit 240. The second high frequency power source 253 may apply RF power to the main body 241 of the showerhead unit 240.

In case of the example according to FIG. 5, the second high frequency power source 253 may be installed on the second transmission line 254. In case of the example according to FIG. 6, the second high frequency power source 253 may not be installed on the second transmission line 254. When the second high frequency power source 253 is installed on the second transmission line 254, the plasma generating unit 250 may apply a multi-frequency to the substrate treating apparatus 200.

Recently, there is a need for improvement in a high aspect ratio contact (HARC) process in accordance with semiconductor integration and high-end processes. As a way of improving the high aspect ratio contact process, attempts have been made to change a hardware structure of the substrate treating apparatus 200 for plasma confinement. In the present disclosure, the showerhead unit 240, which includes an upper ground ring (UGR) and is capable of controlling plasma confinement by using the upper ground ring, will be described.

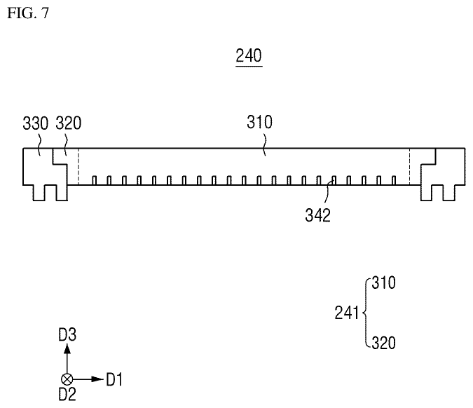

FIG. 7 is an exemplary view illustrating an internal structure of a showerhead unit according to the first embodiment of the present disclosure. Referring to FIG. 7, the showerhead unit 240 may include an inner showerhead 310, an outer showerhead 320, and an upper ring assembly 330.

The inner showerhead 310 is a component constituting a showerhead main body 241, and may include a gas feeding hole 242. The gas feeding hole 242 may be formed by passing through the inner showerhead 310 in the thickness direction D3, and may be formed in the inner showerhead 310 as a plural number. The inner showerhead 310 may provide a process gas to the inner space of the chamber housing CH through the plurality of gas feeding holes 242. The inner showerhead 310 may be provided as a gas distribution assembly that includes a gas distribution plate (GDP).

The outer showerhead 320 constitutes the showerhead main body 241 together with the inner showerhead 310, and may be provided to surround the inner showerhead 310, thereby protecting the inner showerhead 310. The inner showerhead 310 may be provided in a cylindrical shape, and the outer showerhead 320 may be provided in a ring shape, but the shapes of the inner showerhead 310 and the outer showerhead 320 are not necessarily limited thereto. The gas feeding hole 242 may be formed only in the inner showerhead 310, but is not limited thereto, and may be also formed in both the inner showerhead 310 and the outer showerhead 320.

The outer showerhead 320 may be formed of the same material as that of the inner showerhead 310, but is not limited thereto, and the outer showerhead 320 may be formed of a material different from that of the inner showerhead 310. For example, the inner showerhead 310 may be formed of a silicon material or a metal material, and the outer showerhead 320 may be formed of a material having etch resistance.

The upper ring assembly 330 serves to protect the inner showerhead 310 and the outer showerhead 320, and may be provided to surround the outer showerhead 320. The outer showerhead 320 may serve as a spacer for adjusting a gap between the inner showerhead 310 and the upper ring assembly 330. Likewise, the upper ring assembly 330 may serve as a spacer for adjusting a gap between the outer showerhead 320 and the liner unit 260.

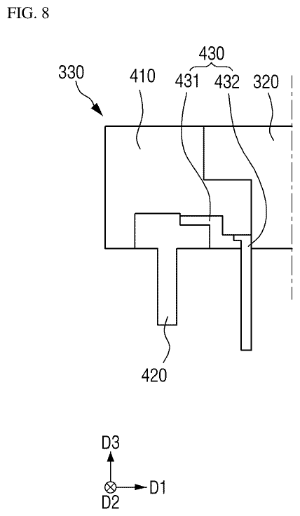

Referring to FIG. 8, the upper ring assembly 330 may include a first portion 410, a second portion 420, and a third portion 430. FIG. 8 is an exemplary view illustrating an internal structure of an upper ring assembly according to the first embodiment of the present disclosure.

The first portion 410 may be disposed above the second portion 420 and the third portion 430. The first portion 410 may be formed to include a metal material. For example, the first portion 410 may be formed to include an aluminum (Al) material. The first portion 410 may be provided as a top plate. The first portion 410 may be connected to the window module WM installed thereon. Alternatively, the first portion 410 may be a portion of the window module WM.

The second portion 420 and the third portion 430 may be disposed below the first portion 410. The second portion 420 may be disposed on one side below the first portion 410, and the third portion 430 may be disposed on the other side below the first portion 410. The second portion 420 and the third portion 430 may be disposed in parallel below the first portion 410.

The second portion 420 may be extended downward based on the height direction D3 of the chamber housing CH. The second portion 420 may be connected to the liner unit 260 installed inside the chamber housing CH. Alternatively, the second portion 420 may be a portion of the liner unit 260. The second portion 420 may be provided as a heated liner by absorbing heat from plasma generated in the inner space of the chamber housing CH. Alternatively, the second portion 420 may be provided as a heated liner by absorbing heat from the inner showerhead 310 and the outer showerhead 320, which are heated by plasma, i.e., the showerhead main body 241. When connected to the liner unit 260, the second portion 420 may be provided as a heated liner shield ring installed on the liner unit 260.

The third portion 430 may serve as a ground between the showerhead main body 241 and the liner unit 260. The third portion 430 may be stacked on the second portion 420 or the liner unit 260, and may serve to perform grounding by forming an RF path in its lower structure (e.g., the liner unit 260). Also, the third portion 430 may serve to prevent particles from flowing between the showerhead main body 241 and the liner unit 260. The third portion 430 may be provided as an upper ground ring (UGR). The third portion 430 may include a spacer 431 and a bulk liner 432.

The spacer 431 may be provided to adjust a gap between the showerhead main body 241 and the second portion 420. The spacer 431 may be formed of a metal material. For example, the spacer 431 may be formed of an aluminum (Al) material.

The spacer 431 may be electrochemically treated to form an oxide layer on a surface thereof. The spacer 431 may be treated to form an oxide layer on a surface thereof by using an anodizing method. The spacer 431 may be electrochemically surface-treated using an electrolyte containing a hydrogen component (H-Anodizing). The spacer 431 may be surface-treated to form an oxide layer on a remaining surface other than a ground surface. The spacer 431 may maintain the original function (i.e., grounding and inflow prevention of particles) of the third portion 430 through the surface treatment as described above.

The bulk liner 432 is coupled to the spacer 431, and may be formed to be extended from a lateral portion of the showerhead main body 241 to a plasma space. That is, the bulk liner 432 may be extended to a space between the substrate support unit 210 and the showerhead unit 240. The bulk liner 432 may restrict a distribution zone of the process gas supplied to the inner space of the chamber housing CH through the plurality of gas feeding holes 242, thereby obtaining an effect of controlling plasma confinement.

The bulk liner 432 may be formed to include a silicon (Si) material. The bulk liner 432 may include only a silicon material and thus may be provided as a single Si bulk liner, but is not limited thereto, and may further include another material in addition to silicon and thus may be also provided as a multi-Si bulk liner.

When the bulk liner 432 is provided as a single Si bulk liner, the probability of particles adsorbed onto a surface of the bulk liner 432 may be more lowered than the case that the bulk liner 432 is provided as a multi-Si bulk liner. When the bulk liner 432 is provided as a single Si bulk liner, the amount of particles flowing between the showerhead main body 241 and the liner unit 260 may be minimized.

When the bulk liner 432 is provided as a single Si bulk liner, the bulk liner 432 may be formed of a silicon material having a low resistance coefficient. The bulk liner 432 may be formed of a silicon material having a resistance coefficient less than a reference value. The bulk liner 432 may be formed of a low resistance silicon material. For example, the bulk liner 432 may be formed of a silicon material having an electrical resistance rate of 0.6 mΩ·cm to 1.0 mΩ·cm or less. When the bulk liner 432 is formed of a low resistance silicon material, an effect of lowering the possibility of arcing due to a potential difference during a substrate treating process may be obtained as compared with the case that the bulk liner 432 is formed of a high resistance silicon material. The high resistance silicon material refers to a silicon material having a resistance coefficient greater than the reference value. In addition, when the bulk liner 432 is formed of a low resistance silicon material, an effect of lowering the possibility of arcing due to a potential difference during a substrate treating process may be obtained as compared with the case that the bulk liner 432 is formed of an intermediate resistance silicon material. The intermediate resistance silicon material refers to a silicon material having a resistance coefficient equal to the reference value.

When provided as a multi-Si bulk liner, the bulk liner 432 may include a material other than a silicon material. The other material may be a material capable of lowering electrical resistance of a silicon material. The other material may be a material having a low resistance coefficient, and may be a material having a resistance coefficient smaller than the reference value. The other material may be a low resistance material. For example, the other material may be a material having an electrical resistance rate of 0.6 mΩ·cm to 1.0 mΩ·cm or less. When the bulk liner 432 is provided as described above, the influence of the by-product by the process gas and grounding of the RF path may be reduced. When the bulk liner 432 is provided as a multi-Si bulk liner, a silicon material may be also provided as a material having a low resistance coefficient.

When the bulk liner 432 is provided as a multi-Si bulk liner, a material other than the silicon material may be a carbon material. That is, the bulk liner 432 may include a SiC material and thus may be provided as a multi-Si bulk liner.

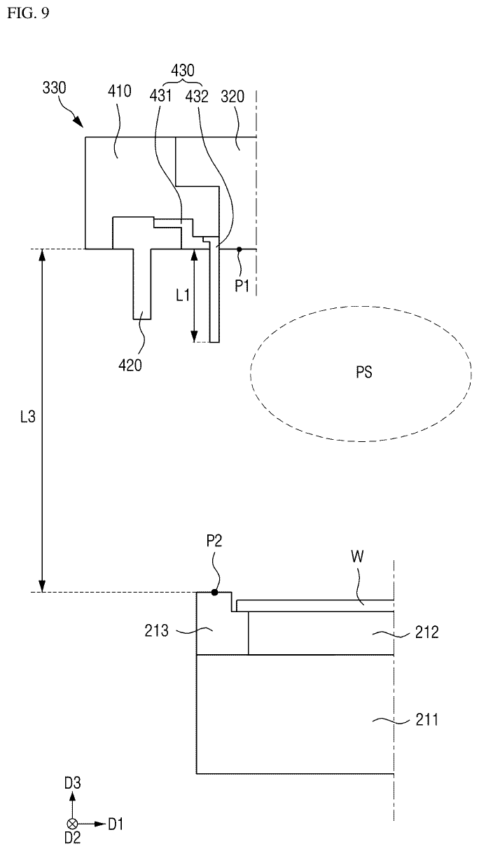

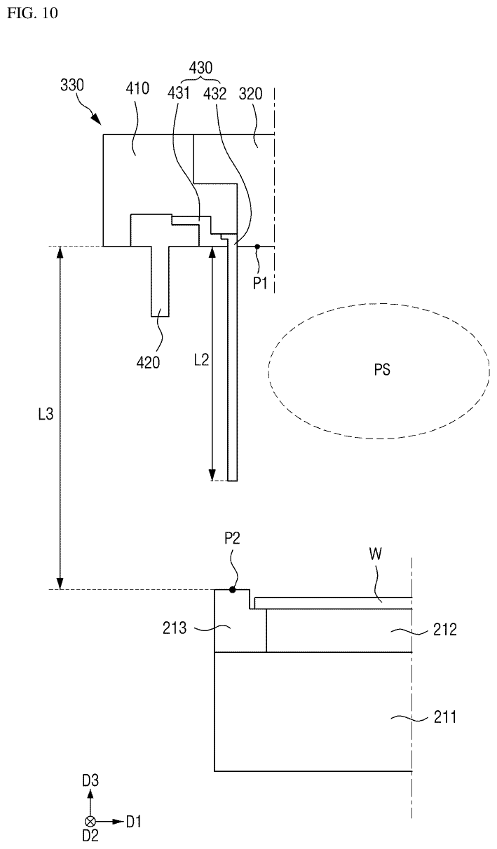

The bulk liner 432 may be extended in the height direction D3 of the liner unit 260, which is provided in a ring shape, as a longitudinal direction. Referring to FIG. 9, the bulk liner 432 may be formed to be extended by a first length L1 from a side of the outer showerhead 320 to a plasma space PS. Alternatively, referring to FIG. 10, the bulk liner 432 may be formed to be extended by a second length L2 from the side of the outer showerhead 320 to the plasma space PS. The first length L1 and the second length L2 refer to lengths protruded from the surface of the upper ring assembly 330 in a downward direction D3. The second length L2 may be greater than the first length L1 (L2>L1). The plasma space PS may include both the plasma zone and the process zone, which are described above. Alternatively, the plasma space PS may include only one of the plasma zone and the process zone.

The bulk liner 432 may be formed to be extended from a lower surface of the outer showerhead 320 in a direction in which an upper surface of the ring structure 213 is positioned. When the lower surface of the outer showerhead 320 is defined as a first point P1 and the upper surface of the ring structure 213 is defined as a second point P2, the bulk liner 432 may be formed to be extended from the first point P1 in a direction in which the second point P2 is positioned. The bulk liner 432 may be formed to be extended through the plasma space PS. A length of the bulk liner 432 may have a level equivalent to that of the first point P1 as a minimum value, and a distance from the first point P1 to the second point P2 may be a maximum value. The minimum value may be 0, and the maximum value may be L3.

The first length L1 may be greater than 0 and smaller than 0.5*L3 (0<L1<0.5*L3). When the first length L1 is smaller than the second length L2, the first length L1 may be equal to or greater than 0.5*L3. When the bulk liner 432 is formed to have the first length L1, the bulk liner 432 may be formed to be more protruded to the plasma space PS than the lower surface of the outer showerhead 320.

The second length L2 may be equal to or greater than 0.5*L3 and less than L3 (0.5*L2<L3). When the second length L2 is greater than the first length L1, the second length L2 may be less than 0.5*L3. When the bulk liner 432 is formed to have the second length L2, the bulk liner 432 may be formed to have a length that is not in contact with the ring structure 213.

When the bulk liner 432 is formed to have the second length L2, the bulk liner 432 may be positioned to be closer to the substrate support unit 210 than the case that the bulk liner 432 is formed to have the first length L1. On the other hand, when the bulk liner 432 is formed to have the second length L2, the bulk liner 432 may be positioned to be farther from the showerhead unit 140 than the case that the bulk liner is formed to have the first length L1. FIG. 9 is an exemplary view illustrating structural characteristics of a bulk liner according to the first embodiment of the present disclosure. FIG. 10 is an exemplary view illustrating structural characteristics of a bulk liner according to the second embodiment of the present disclosure.

When the bulk liner 432 is formed to have the first length L1, restriction for the distribution zone of the process gas may be more alleviated than the case that the bulk liner 432 is formed to have the second length L2. When the bulk liner 432 is formed to have the first length L1, plasma confinement may be more alleviated than the case that the bulk liner 432 is formed to have the second length L2. When the bulk liner 432 is formed to have the first length L1, an etch rate for an entire surface of the substrate W may be more lowered than the case that the bulk liner 432 is formed to have the second length L2.

When the bulk liner 432 is formed to have the second length L2, restriction for the distribution zone of the process gas may be more alleviated than the case that the bulk liner 432 is formed to have the first length L1. When the bulk liner 432 is formed to have the second length L2, plasma confinement may be more enhanced than the case that the bulk liner 432 is formed to have the first length L1. When the bulk liner 432 is formed to have the second length L2, the etch rate ER for the entire surface of the substrate W may be more increased than the case that the bulk liner 432 is formed to have the first length L1.

As described above, the case that the bulk liner 432 is formed to have the first length L1 and the case that the bulk liner 432 is formed to have the second length L2 have been described through comparison. The bulk liner 432 may be modified to have various lengths within a range greater than 0 and smaller than L3 depending on how much the distribution zone of the process gas is restricted in the inner space of the chamber housing CH. Alternatively, the bulk liner 432 may be modified to have various lengths within a range greater than 0 and smaller than L3 depending on how much the distribution zone of the plasma is restricted in the inner space of the chamber housing CH. Alternatively, the bulk liner 432 may be modified to have various lengths within a range greater than 0 and smaller than L3 depending on which line is to be matched with the etch rate for the entire surface of the substrate W or an edge portion of the substrate W.

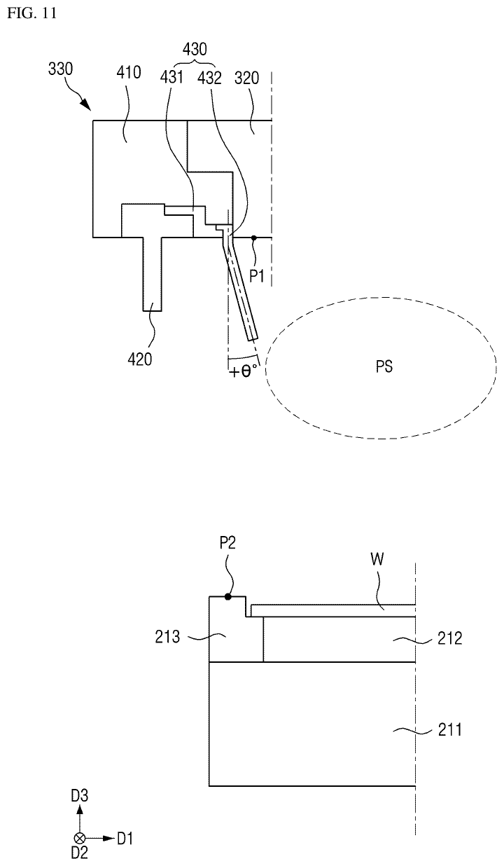

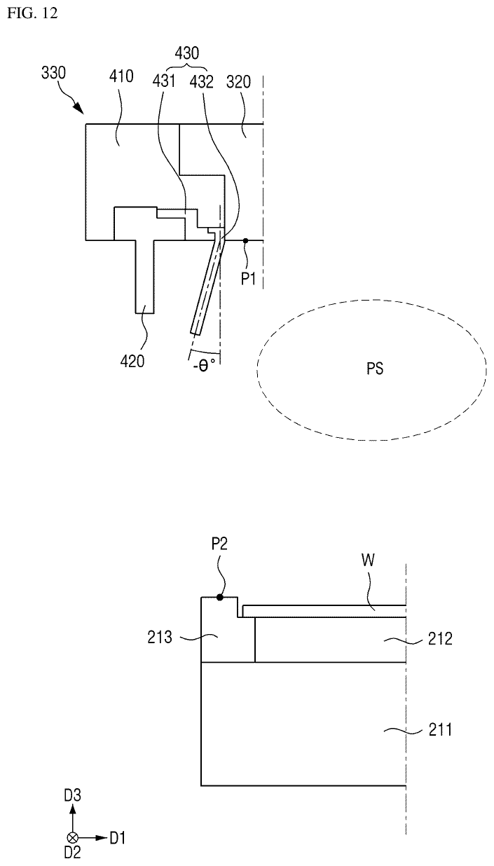

The bulk liner 432 may be extended in the vertical direction D3 inside the chamber housing CH, but is not limited thereto. The bulk liner 432 may be formed to be inclined with respect to the vertical direction D3. Referring to FIG. 11, the bulk liner 432 may be formed to be inclined in an inward direction rather than the vertical direction D3 inside the chamber housing CH. The bulk liner 432 may be formed to be inclined by an angle of +θ. Alternatively, referring to FIG. 12, the bulk liner 432 may be formed to be inclined in an outward direction rather than the vertical direction D3 inside the chamber housing CH. The bulk liner 432 may be formed to be inclined by an −θ angle. FIG. 11 is an exemplary view illustrating structural characteristics of a bulk liner according to the third embodiment of the present disclosure. FIG. 12 is an exemplary view illustrating structural characteristics of a bulk liner according to the fourth embodiment of the present disclosure.

When the bulk liner 432 is formed to be inclined in an inward direction, restriction for the distribution zone of the process gas may be more enhanced than the case that the bulk liner 432 is formed to be inclined in an outward direction. When the bulk liner 432 is formed to be inclined in an inward direction, plasma confinement may be more enhanced than the case that the bulk liner 432 is formed to be inclined in an outward direction. When the bulk liner 432 is formed to be inclined in an inward direction, the etch rate for the entire surface of the substrate W may be more increased than the case that the bulk liner 432 is formed to be inclined in an outward direction. When the bulk liner 432 is formed to be inclined in an inward direction, the etch rate for the edge portion of the substrate W may be more increased than the case that the bulk liner 432 is formed to be inclined in an outward direction.

When the bulk liner 432 is formed to be inclined in an outward direction, restriction for the distribution zone of the process gas may be more alleviated than the case that the bulk liner 432 is formed to be inclined in an inward direction. When the bulk liner 432 is formed to be inclined in an outward direction, plasma confinement may be more alleviated than the case that the bulk liner 432 is formed to be inclined in an inward direction. When the bulk liner 432 is formed to be inclined in an outward direction, the etch rate for the entire surface of the substrate W may be more lowered than when the bulk liner 432 is formed to be inclined in an inward direction. When the bulk liner 432 is formed to be inclined in an outward direction, the etch rate for the edge portion of the substrate W may be more lowered than the case that the bulk liner 432 is formed to be inclined in an inward direction.

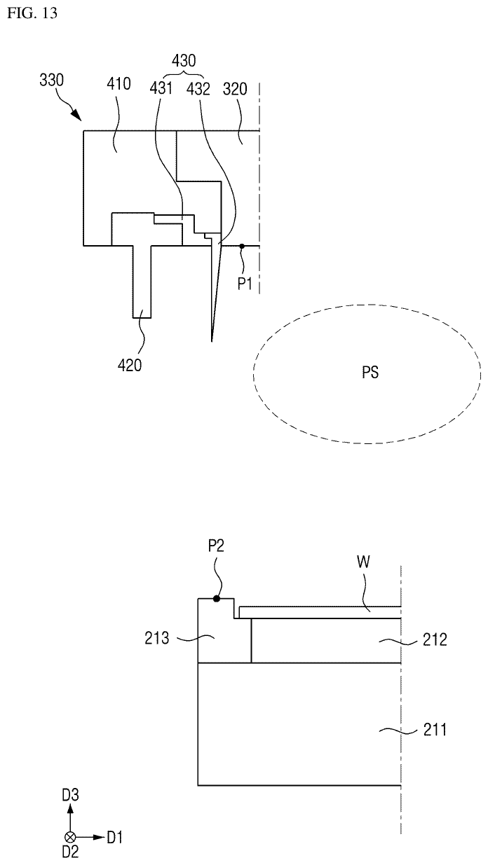

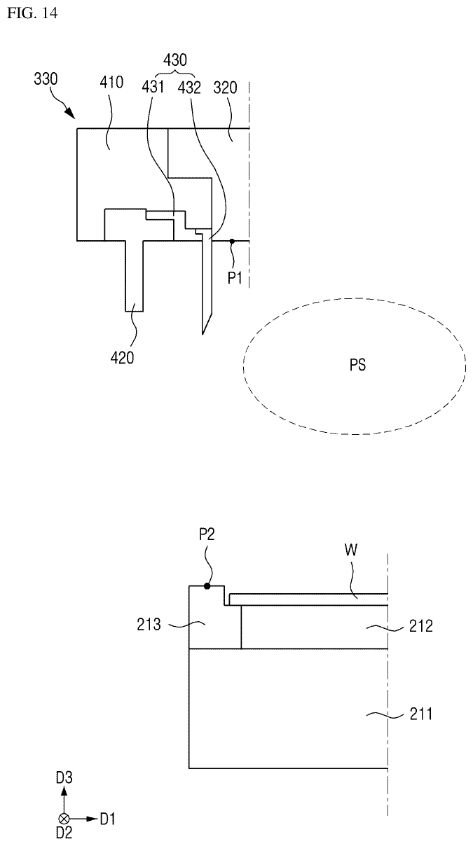

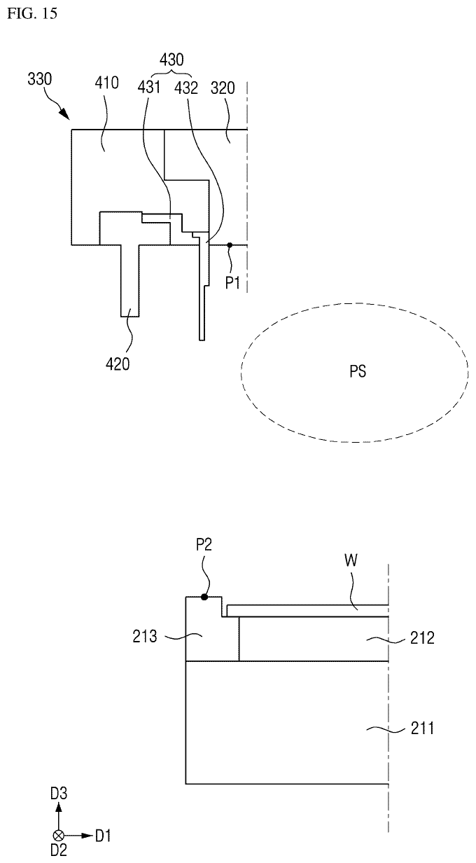

The bulk liner 432 may be formed in a planar shape. However, in order to control the plasma zone inside the chamber housing CH, various modifications may be made in the shape of the bulk liner 432. Referring to FIG. 13, the bulk liner 432 may have one surface protruded toward the outside and entirely inclined. The inclined surface of the bulk liner 432 may be disposed in an inward direction inside the chamber housing CH. Alternatively, referring to FIG. 14, the bulk liner 432 may have one surface protruded toward the outside and partially inclined. As described above, the partially inclined surface of the bulk liner 432 may be disposed in an inward direction inside the chamber housing CH. Alternatively, referring to FIG. 15, the bulk liner 432 may have one surface protruded toward the outside and formed in a hierarchical shape. The hierarchical surface of the bulk liner 432 may be disposed in an inward direction inside the chamber housing CH.

When the bulk liner 432 is formed in a non-planar shape as described with reference to FIGS. 13 to 15, restriction for the distribution zone of the process gas may be more alleviated than the case that the bulk liner 432 is formed in a planar shape. When the bulk liner 432 is formed in a non-planar shape, plasma confinement may be more alleviated than the case that the bulk liner 432 is formed in a planar shape. When the bulk liner 432 is formed in a non-planar shape, the etch rate for the entire surface of the substrate W may be more lowered than the case that the bulk liner 432 is formed in a planar shape. When the bulk liner 432 is formed in a non-planar shape, the etch rate for the edge portion of the substrate W may be more lowered than the case that the bulk liner is formed in a planar shape. FIG. 13 is an exemplary view illustrating structural characteristics of a bulk liner according to the fifth embodiment of the present disclosure. FIG. 14 is an exemplary view illustrating structural characteristics of a bulk liner according to the sixth embodiment of the present disclosure. FIG. 15 is an exemplary view illustrating structural characteristics of a bulk liner according to the seventh embodiment of the present disclosure.

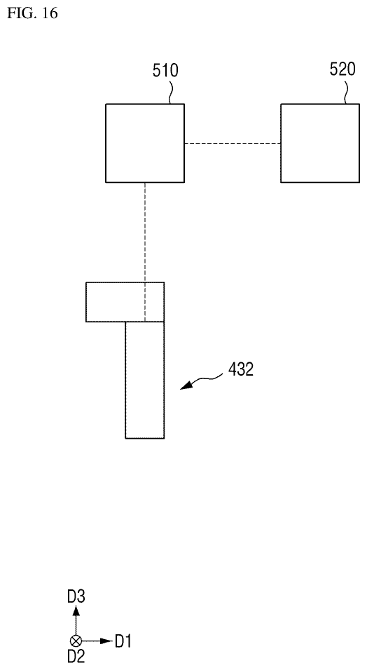

The length of the bulk liner 432 may be fixed, but is not limited thereto, and the length thereof may be changed in order to control the plasma zone in accordance with an internal environment of plasma. FIG. 16 is a first exemplary view illustrating structural characteristics of a bulk liner according to the eighth embodiment of the present disclosure.

The bulk liner 432 may be connected to the driving module 510 and the control module 520. The driving module 510 may provide power for extending the length of the bulk liner 432. Also, the driving module 510 may provide power for reducing the length of the bulk liner 432. The control module 520 may control the driving module 510 to provide power to the bulk liner 432.

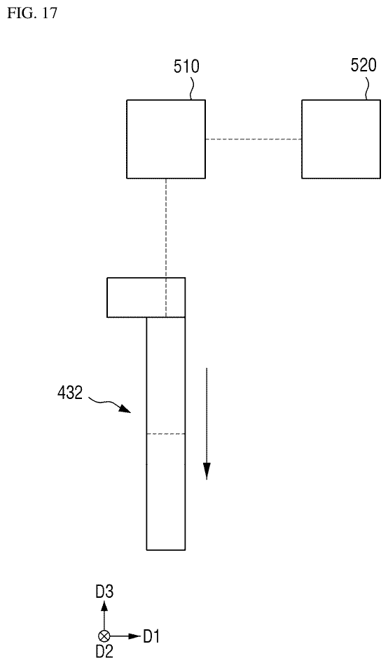

Referring to FIG. 17, the length of the bulk liner 432 may be extended using the power provided by the driving module 510. The length of the bulk liner 432 may be extended in a direction in which the upper surface of the ring structure 213 is positioned. That is, the length of the bulk liner 432 may be extended in a direction in which the second point P2 is positioned. FIG. 17 is a second exemplary view illustrating structural characteristics of a bulk liner according to the eighth embodiment of the present disclosure.

When the length of the bulk liner 432 is extended, restriction for the distribution zone of the process gas may be more enhanced than before. When the length of the bulk liner 432 is extended, plasma confinement may be more enhanced than before. When the length of the bulk liner 432 is extended, the etch rate for the entire surface of the substrate W may be more increased than before. When the length of the bulk liner 432 is extended, the etch rate for the edge portion of the substrate W may be more increased than before.

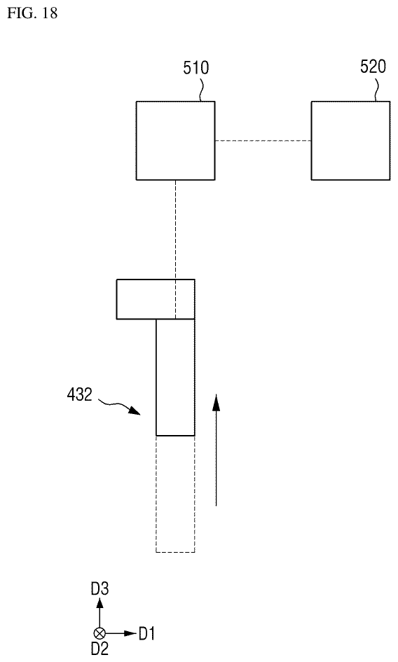

Referring to FIG. 18, the length of the bulk liner 432 may be reduced using the power provided by the driving module 510. The length of the bulk liner 432 may be reduced in a direction in which the lower surface of the outer showerhead 320 is positioned. That is, the length of the bulk liner 432 may be reduced in a direction in which the first point P1 is positioned. FIG. 18 is a third exemplary view illustrating structural characteristics of a bulk liner according to the eighth embodiment of the present disclosure.

When the length of the bulk liner 432 is reduced, restriction for the distribution zone of the process gas may be more alleviated than before. When the length of the bulk liner 432 is reduced, plasma confinement may be more alleviated than before. When the length of the bulk liner 432 is reduced, the etch rate for the entire surface of the substrate W may be more lowered than before. When the length of the bulk liner 432 is reduced, the etch rate for the edge portion of the substrate W may be more lowered than before.

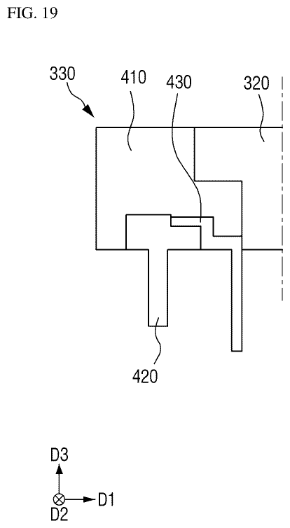

The case that the third portion 430 is formed to include a spacer 431 and a bulk liner 432 has been described as above. The third portion 430 may be formed of a plurality of components. For example, the third portion 430 may be formed of two components including a spacer 431 and a bulk liner 432, but is not limited thereto. The third portion 430 may be formed of a single component. Referring to FIG. 19, when the third portion 430 is formed of a single component, the third portion 430 may not be divided into a spacer 431 and a bulk liner 432.

When the third portion 430 is formed of a single component, various structural features of the bulk liner 432 may be applied to the third portion 430. Various structural features of the bulk liner 432 have been described above with reference to FIGS. 8 to 18, and thus their detailed description will be omitted herein. Further, the third portion 430 may be provided as a single silicon bulk liner containing only a silicon material, but is not limited thereto, and may be provided as a multi-silicon bulk liner further containing a material other than a silicon material. FIG. 19 is an exemplary view illustrating an internal structure of an upper ring assembly according to the second embodiment of the present disclosure.

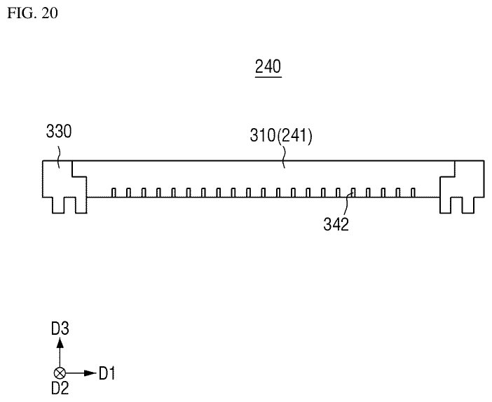

The case that the showerhead unit 240 includes an inner showerhead 310, an outer showerhead 320 and an upper ring assembly 330 has been described above with reference to FIG. 7, but the present disclosure is not limited thereto. The showerhead unit 240 may also include only the inner showerhead 310 and the upper ring assembly 330. Referring to FIG. 20, the upper ring assembly 330 may be formed to be in close contact with the side of the inner showerhead 310. It is obvious that various structural characteristics of the upper ring assembly 330 described with reference to FIGS. 8 to 19 may be equally applied to the upper ring assembly 330 of FIG. 20. FIG. 20 is an exemplary view illustrating an internal structure of a showerhead unit according to the second embodiment of the present disclosure.

The present disclosure is related with a change in an upper ground ring structure for plasma confinement. The change is a change in a liner type capable of confining plasma in a direction of a process gap in order to improve a process effect through an increase in plasma density in accordance with recent semiconductor integration and high-end processes. In the present disclosure, the upper ground ring may be manufactured by being divided into two body parts: an Al spacer and a Si bulk liner. One of the two body parts manufactured is an Al material spacer capable of maintaining grounding with a heated liner, and the other one is a Si material bulk liner for plasma confinement.

The bulk liner is extended from UGR in a downward direction in a liner structure, and has an effect of concentrating plasma sprayed from the upper showerhead in the form of gas. The length of the bulk liner is extended in a direction of a process volume for chamber pumping, making sure of an EPD viewing window, and operating an end effector so that there is no difference from the existing working process. In addition, the bulk liner is made of a single Si low-resistance material that may solve the particle issue and enhance grounding. According to the present disclosure, a plasma confinement effect may be obtained by changing the UGR structure, and thus ER uniformity and process effect may be expected to be improved.

Although the embodiments of the present disclosure have been described with reference to the accompanying drawings, it will be apparent to those skilled in the art that the present disclosure can be embodied in other specific forms without departing from the technical concepts and characteristics of the present disclosure. Thus, the above-described embodiments are to be considered in all respects as illustrative and not restrictive.

What is claimed is:

1. A substrate treating apparatus comprising:
a chamber housing providing a space in which a substrate is treated;
a substrate support unit disposed inside the chamber housing, supporting the substrate;
a showerhead unit disposed inside the chamber housing, providing a process gas; and
a plasma generating unit generating plasma for treating the substrate by using the process gas,
wherein the showerhead unit includes:
a showerhead main body that includes a plurality of gas feeding holes to provide the process gas; and
an upper ring assembly surrounding the showerhead main body, and
the upper ring assembly includes a portion extended in a direction in which the substrate support unit is positioned.

2. The substrate treating apparatus of claim 1, wherein the showerhead main body includes:
an inner showerhead; and
an outer showerhead surrounding the inner showerhead, and
the gas feeding hole is formed in the inner shower head.

3. The substrate treating apparatus of claim 1, wherein the upper ring assembly includes:
a first portion;
a second portion disposed on one side below the first portion; and
a third portion disposed on the other side below the first portion, and
the third portion is grounded.

4. The substrate treating apparatus of claim 3, wherein the third portion is disposed to be closer to the showerhead main body than the second portion.

5. The substrate treating apparatus of claim 3, wherein the third portion includes:
a spacer providing a constant spacing between the showerhead main body and the second portion; and
a bulk liner coupled to the spacer and extended in a direction in which the substrate support unit is positioned.

6. The substrate treating apparatus of claim 5, wherein the spacer is provided with an oxide layer formed on a surface.

7. The substrate treating apparatus of claim 6, wherein the spacer is provided with an oxide layer formed on the other surface except a ground surface.

8. The substrate treating apparatus of claim 5, wherein the spacer is formed of a metal material.

9. The substrate treating apparatus of claim 5, wherein the bulk liner includes a first material, and
the first material is a silicon material.

10. The substrate treating apparatus of claim 9, wherein the bulk liner further includes a second material in addition to the first material, and
the second material is a material that lowers electrical resistance of the first material.

11. The substrate treating apparatus of claim 10, wherein the second material is a carbon material.

12. The substrate treating apparatus of claim 1, wherein a length of the extended portion is determined depending on the degree of restriction for a distribution zone of the process gas or the plasma, or an etch rate for the substrate.

13. The substrate treating apparatus of claim 1, wherein the extended portion is formed straight in a first direction or formed to be inclined with respect to the first direction.

14. The substrate treating apparatus of claim 13, wherein the first direction is a direction connecting the substrate support unit with the showerhead unit.

15. The substrate treating apparatus of claim 1, wherein the extended portion has an entire surface of a planar shape or one surface of a non-planar shape.

16. The substrate treating apparatus of claim 15, wherein the one surface is disposed in an inward direction inside the chamber housing.

17. The substrate treating apparatus of claim 1, wherein the extended portion has a length varied depending on a plasma environment inside the chamber housing.

18. The substrate treating apparatus of claim 1, wherein the extended portion has a length shorter than a distance between the showerhead unit and the substrate support unit.

19. A showerhead unit installed in an apparatus for treating a substrate by using plasma, the showerhead unit comprising;
an inner showerhead including a plurality of gas feeding holes providing a process gas for generating the plasma;
an outer showerhead surrounding the inner showerhead; and
an upper ring assembly surrounding the outer showerhead,
wherein the upper ring assembly includes a portion extended in a direction in which the substrate support unit is positioned.

20. A substrate treating apparatus comprising:
a chamber housing providing a space in which a substrate is treated;
a substrate support unit disposed inside the chamber housing, supporting the substrate;
a showerhead unit disposed inside the chamber housing, providing a process gas; and
a plasma generating unit generating plasma for treating the substrate by using the process gas,
wherein the showerhead unit includes:
an inner showerhead including a plurality of gas feeding holes for providing the process gas;
an outer showerhead surrounding the inner showerhead; and
an upper ring assembly surrounding the outer showerhead,
the upper ring assembly includes:
a first portion;
a second portion disposed on one side below the first portion; and
a third portion disposed on the other side below the first portion, grounded and disposed to be closer to the outer showerhead than the second portion, and
the third portion includes:
a spacer providing a constant spacing between the outer showerhead and the second portion; and
a bulk liner coupled to the spacer and extended in a direction in which the substrate support unit is positioned.
